(19) United States
(12) Patent Application Publication
(10) Pub. No.: US 2025/0020520 A1
(43) Pub. Date: Jan. 16, 2025

(54) Heat Detection Device

(71) Applicant: Daifuku Co., Ltd., Osaka-shi (JP)

(72) Inventor: Hiroumi Murai, Hinocho (JP)

(21) Appl. No.: 18/766,935

(22) Filed: Jul. 9, 2024

(30) Foreign Application Priority Data
Jul. 10, 2023 (JP) 2023-112915

(51) Int. Cl. G01K 11/06; G01R 27/02; G01R 31/52; H01L 21/677

(52) U.S. Cl. CPC G01K 11/06; G01R 27/02; G01R 31/52; H01L 21/6773

(57) ABSTRACT

A heat detection device includes a short-circuit position detector that detects a short-circuited site at which a first conductive wire and a second conductive wire are short-circuited. The short-circuit position detector includes a switch including at least one make-break contact. The switch switches connection of first branches having a first resistance, second branches having a second resistance, and a third branch having a third resistance to cause the first branches, the second branches, and the third branch to be included in at least one two-terminal circuit and to form at least three two-terminal circuits.

### CROSS-REFERENCE TO RELATED APPLICATIONS

This application claims priority to Japanese Patent Application No. 2023-112915 filed Jul. 10, 2023, the disclosure of which is hereby incorporated by reference in its entirety.

### BACKGROUND OF THE INVENTION

### Field of the Invention

The present invention relates to a heat detection device that detects heat generation of a detection target by detecting a short circuit between a first conductive wire and a second conductive wire resulting from an insulator softening with heat. The first conductive wire and the second conductive wire are adjacent to each other along the detection target with the insulator that softens at a preset temperature disposed between the first conductive wire and the second conductive wire.

### Description of Related Art

The heat detection device that detects heat generation of a detection target by detecting a short circuit between the first conductive wire and the second conductive wire as in the above example may also identify the short-circuited site for restoration of the detection target. Japanese Unexamined Patent Application Publication No. H10-20334 describes a technique for identifying the short-circuited site. More specifically, a probe is connected to a first end of a first conductor and a first end of a second conductor to measure a resistance r0 from the first end of the first conductor to the first end of the second conductor through the short-circuited site. The resistance r0 is R1+r+R2, where R1 is the resistance between the first end of the first conductor and the short-circuited site, r is the resistance between the first conductor and the second conductor at the short-circuited site, and R2 is the resistance between the first end of the second conductor and the short-circuited site. The line length between the first end of the first conductor and the short-circuited site and the line length between the first end of the second conductor and the short-circuited site are substantially equal, and thus R1 is estimated to be equal to R2. In the above patent literature, the resistance r at the short-circuited site is far smaller than R1 and R2, and is estimated to be zero, and r0 is approximated as r0=2·R1. With a line length L0 of the first conductor and the second conductor and a resistance R0 of the entire line being known, a length x from the first end of the first conductor to the short-circuited site is calculated as x=(R1/R0)·L0 (the same applies to the first end of the second conductor).

However, when the first conductive wire and the second conductive wire are short-circuited, the first conductor and the second conductor at the short-circuited site may be in contact with each other in various manners, and thus the resistance may vary. When, for example, the insulator between the first conductive wire and the second conductive wire softens gradually, the first conductive wire and the second conductive wire may be short-circuited while having a relatively large resistance. In this case as well, heat generation of the detection target is to be detected promptly to accurately identify the short-circuited site generating heat. However, when the resistance between the first conductor and the second conductor at the short-circuited site is estimated to be zero as in the above manner, estimation of the short-circuited site can have a large error.

### SUMMARY OF THE INVENTION

In response to the above, techniques are awaited for accurately identifying a short-circuited site based on a resistance between a first conductive wire and a second conductive wire at the short-circuited site.

A heat detection device in response to the above includes a first conductive wire, a second conductive wire, and a short-circuit position detector. The first conductive wire includes a first contact and a second contact at opposite ends of the first conductive wire. The second conductive wire includes a third contact and a fourth contact at opposite ends of the second conductive wire. The second conductive wire is adjacent to the first conductive wire along a detection target with an insulator between the first conductive wire and the second conductive wire. The insulator softens at a preset temperature. The short-circuit position detector detects a short-circuited site at which the first conductive wire and the second conductive wire are short-circuited. The heat detection device detects heat generation of the detection target by detecting a short circuit between the first conductive wire and the second conductive wire. The short circuit results from the insulator softening with heat. The short-circuit position detector includes a first target contact selected from at least one of the first contact, the second contact, the third contact, or the fourth contact, a second target contact selected from at least one of the first contact, the second contact, the third contact, or the fourth contact excluding the first target contact, a reference resistance connected to at least one of a positive electrode or a negative electrode, a first reference contact connected to the positive electrode or connected to the positive electrode through the reference resistance, a second reference contact connected to the negative electrode or connected to the negative electrode through the reference resistance, a voltage detector that detects a target voltage between the first target contact and the second target contact, and a switch including at least one make-break contact. The switch switches electric connection between at least the first contact, the second contact, the third contact, or the fourth contact and the first reference contact or the second reference contact to switch a circuit configuration of two-terminal circuits each including the first target contact and the second target contact as terminals. The switch switches, in response to the first conductive wire and the second conductive wire being short-circuited at the short-circuited site, connection of first branches, second branches, and a third branch to cause the first branches, the second branches, and the third branch to be included in at least one of the two-terminal circuits and to form at least three two-terminal circuits each including the first target contact and the second target contact as terminals. The first branches are branches having substantially a same first resistance and are a branch extending from the first contact to a first short-circuit point and a branch extending from the third contact to a second short-circuit point. The second branches are branches having substantially a same second resistance and are a branch extending from the first short-circuit point to the second contact and a branch extending from the second short-circuit point to the fourth contact. The third branch is a branch having a third resistance and extending between the first short-circuit point and the second short-circuit point. The first short-circuit point is a contact at the short-circuited site in the first conductive wire. The second short-circuit point is a contact at the short-circuited site in the second conductive wire.

The heat detection device with this structure includes the switch that switches the connection between the first conductive wire or the second conductive wire and the first reference contact nearer the positive electrode or the second reference contact nearer the negative electrode to form the at least three two-terminal circuits. Each two-terminal circuit includes at least one of an unknown first resistance, an unknown second resistance, or an unknown third resistance. With simultaneous equations based on the three two-terminal circuits, the unknown three resistances can be determined. Determining the third resistance that may vary depending on the form of a short circuit at the short-circuited site allows accurate determination of the first resistance and the second resistance. The resistance of the conductive wire has a linear relationship with the length of the conductive wire. Thus, determining the resistance of the conductive wire, or the first resistance and the second resistance, allows accurate estimation of the short-circuited site. More specifically, the heat detection device with this structure can accurately identify the short-circuited site based on the resistance between the first conductive wire and the second conductive wire at the short-circuited site.

Further features and advantageous effects of the heat detection device will be apparent from exemplary and nonlimiting embodiments described below with reference to the drawings.

### BRIEF DESCRIPTION OF THE DRAWINGS

The terms Fig., Figs., Figure, and Figures are used interchangeably in the specification to refer to the corresponding figures in the drawings.

FIG. 1 is a front view of an example article transport vehicle.

FIG. 2 is a circuit block diagram of a short-circuit detection device in a heat detection device, schematically showing its example structure.

FIG. 3 is an equivalent circuit diagram of a thermal line with a short circuit.

FIG. 4 is a circuit block diagram of a first example of a two-terminal circuit that is formed when selected by the same switch as in FIGS. 5 and 6.

FIG. 5 is a circuit block diagram of a second example of the two-terminal circuit that is formed when selected by the same switch as in FIGS. 4 and 6.

FIG. 6 is a circuit block diagram of a third example of the two-terminal circuit that is formed when selected by the same switch as in FIGS. 4 and 5.

FIG. 7 is a diagram of two-terminal circuits of three different types that are formed when selected by a switch with a configuration different from the configuration in FIGS. 4 to 6 and their combined resistances.

FIG. 8 is a diagram of two-terminal circuits of three different types that are formed when selected by a switch with a configuration different from the configuration in FIGS. 4 to 7 and their combined resistances.

FIG. 9 is an equivalent circuit diagram of an example circuit including a switch that can form a two-terminal circuit shown in FIGS. 10 to 12.

FIG. 10 is a diagram of a two-terminal pair circuit (four-terminal circuit) with a switchable connection between a first branch, a second branch, and a third branch to form a two-terminal circuit.

FIG. 11 is a diagram of multiple example two-terminal circuits each including a single contact selectively connected to a first target contact for detecting a target voltage among a first contact, a second contact, a third contact, and a fourth contact.

FIG. 12 is a diagram of multiple example two-terminal circuits each including two contacts selectively connected to a first target contact for detecting a target voltage among a first contact, a second contact, a third contact, and a fourth contact.

FIG. 13 is a diagram of multiple example two-terminal circuits each including three contacts selectively connected to a first target contact for detecting a target voltage among a first contact, a second contact, a third contact, and a fourth contact.

### DESCRIPTION OF THE INVENTION

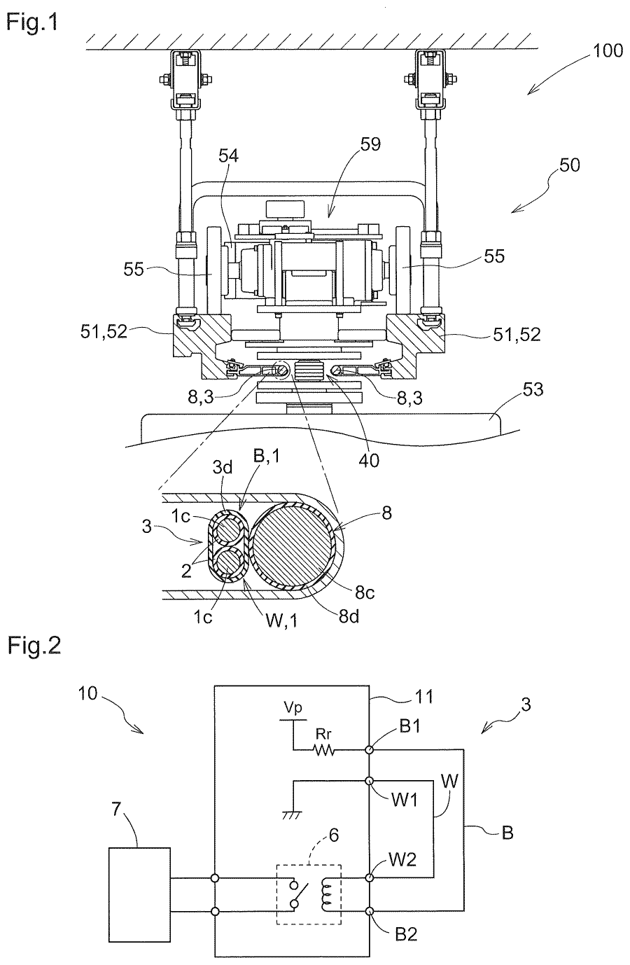

A heat detection device according to an embodiment will be described below with reference to the drawings. The heat detection device is usable in, for example, an article transport facility 100 including an article transport vehicle 50. As shown in FIG. 1, the article transport facility 100 includes feed lines 8 that extend along travel rails 52 forming a movement path 51 for the article transport vehicle 50 to contactlessly feed power to the article transport vehicle 50, and thermal lines 3 extending along the feed lines 8.

The article transport vehicle 50 in the present embodiment includes a traveler 59 that is guided along a pair of travel rails 52 hung from the ceiling to travel along the movement path 51, a transport vehicle body 53 disposed below the travel rails 52 and hung and supported by the traveler 59, and a power receiver 40 that contactlessly receives driving power from the feed lines 8 extending along the movement path 51. The transport vehicle body 53 includes an article support (not shown) that is vertically movable and supports an article being hung. The article transport vehicle 50 transports, for example, front opening unified pods (FOUPs) containing semiconductor substrates or glass substrates to be used as a material for displays.

The traveler 59 includes a pair of travel wheels 55 that are drivable by a drive motor 54 to rotate. The travel wheels 55 roll on the upper surfaces of the travel rails 52 that serve as traveling surfaces. The traveler 59 further includes components such as the drive motor 54 for traveling and a drive circuit for the drive motor 54. The traveler 59 drives the article transport vehicle 50 to travel along the travel rails 52. The transport vehicle body 53 includes, for example, components such as an actuator that lifts and lowers the article support and an actuator that drives a grip for an article, and drive circuits for these actuators.

The power for components including the drive motor 54, the actuators, and the drive circuits for driving these components is fed contactlessly from the feed lines 8 to the power receiver 40. In the present embodiment, the feed lines 8, which feed driving power to the article transport vehicle 50 through the power receiver 40, extend parallel to the horizontal surface of the power receiver 40, and on both sides of the power receiver 40 in the path width direction perpendicular to the movement path 51.

In the present embodiment, using wireless power feeding, the power receiver 40 receives power from the feed lines 8, and feeds driving power to the article transport vehicle 50. A high-frequency current is fed to the feed lines 8 as induction lines, causing a magnetic field around the feed lines 8. The power receiver 40 includes a pick-up coil (not shown) and a magnetic core (not shown). The pick-up coil induces power with electromagnetic induction from the magnetic field. The induced alternating current power is converted to direct current by a rectifier circuit such as a full-wave rectifier circuit or a power receiving circuit (not shown) including, for example, a smoothing capacitor, and is fed to the actuators or the drive circuits.

As shown in FIG. 1, each thermal line 3 includes a pair of conductive wires 1 (a first conductive wire B and a second conductive wire W) each covered with an insulator 2 that softens at a preset temperature. One conductive wire 1 is a covered conductor wire including a core 1c formed from a conductor covered with the insulator 2. The two conductive wires 1, or the first conductive wire B and the second conductive wire W, are twisted to form a twisted pair, and further covered with a cover 3d to form the thermal line 3 including the pair of conductive wires 1. The first conductive wire B and the second conductive wire W are identical members manufactured under the same specifications, and have the same resistance per unit length except for errors such as individual differences. In each thermal line 3, the first conductive wire B and the second conductive wire W have the same total length except for errors.

As shown in FIG. 2, the first conductive wire B includes a first contact B1 and a second contact B2 on the respective two ends. The second conductive wire W includes a third contact W1 and a fourth contact W2 on the respective two ends. A first end (first contact B1) of the first conductive wire B nearer the first end of each thermal line 3 is connected to a positive electrode (Vp) of a short-circuit detection device 11. The first end (third contact W1) of the second conductive wire W nearer the first end of each thermal line 3 is connected to a negative electrode (ground) of the short-circuit detection device 11. The second end (second contact B2) of the first conductive wire B and the second end (fourth contact W2) of the second conductive wire W nearer the second end of each thermal line 3 are connected to each other through a relay 6 (described later). A current restrict resistor Rr in FIG. 2 restricts current flowing between the positive electrode and the negative electrode. More specifically, each thermal line 3 is sequentially connected to, between the positive electrode (Vp) and the negative electrode (ground), the positive electrode (Vp), the current restrict resistor Rr, the first conductive wire B, the relay 6, the second conductive wire W, and the ground.

The pair of conductive wires 1 formed from a twisted pair are short-circuited when the insulators 2 soften to allow the cores 1c formed from conductors to come in contact with each other. The cover 3d is formed from a material that does not soften at a temperature at which the insulators 2 soften. Thus, independent of when the insulators 2 soften, each thermal line 3 including the pair of conductive wires 1 covered with the cover 3d reduces the likelihood that the cores 1c are exposed outside. Each feed line 8 includes a feed line body 8c (core) formed from a conductor and a cover 8d formed from an insulator and covering the feed line body 8c.

The thermal lines 3 extend along the feed lines 8 adjacent to or specifically in close contact with the feed lines 8. When the temperature of the feed lines 8 rises, the insulators 2 soften as described above, and the cores 1c come in contact with each other without insulation and are short-circuited. A short circuit is not limited to a state in which the resistance between the core 1c in the first conductive wire B and the core c1 in the second conductive wire W is zero, and includes a state at which the resistance is extra low (equal to or lower than a predetermined resistance). The short-circuit detection device 11 can detect an abnormality (or a temperature rise) of the feed lines 8 by detecting a short circuit while power is being fed through the thermal lines 3.

In the present embodiment, the short-circuit detection device 11 is mounted on the same board as a short-circuit position detector 12 described later with reference to, for example, FIGS. 4 to 9. A controller 7 is also mounted on or connected to the board. The controller 7 functions as a part of the short-circuit detection device 11 and functions as a part of the short-circuit position detector 12. The controller 7 may mainly include a microcomputer. The short-circuit detection device 11 and the short-circuit position detector 12 may be mounted on different boards or connected to different controllers 7. In either case, the lines may be switched between when the first conductive wire B and the second conductive wire W are connected to the short-circuit detection device 11 and when these wires are connected to the short-circuit position detector 12. For example, after the short-circuit detection device 11 detects a short circuit in any thermal line 3, instead of the short-circuit detection device 11, the short-circuit position detector 12 may be connected to the thermal line 3 to identify the short-circuited site.

When the thermal lines 3 has no short circuit while power is being fed through the thermal lines 3, a current flows from the positive electrode (Vp) through the current restrict resistor Rr, the first conductive wire B, a coil in the relay 6, the second conductive wire W, and the ground. For the relay 6 in a normally open contact, for example, when the contact of the relay 6 is closed by the current, two terminals of the controller 7 to which both ends of the contact of the relay 6 are connected are conducting. When a thermal line 3 is short-circuited, a current flows through the short-circuited site. In other words, a current flows from the positive electrode (Vp) through the current restrict resistor Rr, the first conductive wire B, the short-circuited site, the second conductive wire W, and the ground without through the relay 6. This opens the contact of the relay 6, causing the two terminals of the controller 7 to which both ends of the contact of the relay 6 are connected to be nonconducting.

The controller 7 can thus detect a short circuit in the thermal line 3, or more specifically, a short circuit between the first conductive wire B and the second conductive wire W. The relay 6 functions as a short-circuit detector. The controller 7 or a controller different from the controller 7 (e.g., a facility controller in the article transport facility 100 or a controller in a feeding system for feeding power to the feed lines 8) can determine heat generation in the feed lines 8. More specifically, a heat detection device 10 detects heat generation of a detection target (a feed line 8 in this example) by detecting a short circuit between the first conductive wire B and the second conductive wire W resulting from the insulators 2 softening with heat. The first conductive wire B and the second conductive wire W are adjacent to each other along the detection target (the feed line 8) with the insulators 2 that soften at a preset temperature disposed between the first conductive wire B and the second conductive wire W.

When heat generation of a feed line 8 is detected with a short circuit between the first conductive wire B and the second conductive wire W, the operation of the feeding system or the article transport facility 100 is temporarily stopped for restoration. To reduce a lead time for restoration, the short-circuited site of the thermal line 3, or the site of the feed line 8 generating heat may also to be identified. The heat detection device 10 thus further includes the short-circuit position detector 12 (refer to, for example, FIGS. 4 to 9) that detects a short-circuited site BW between the first conductive wire B and the second conductive wire W.

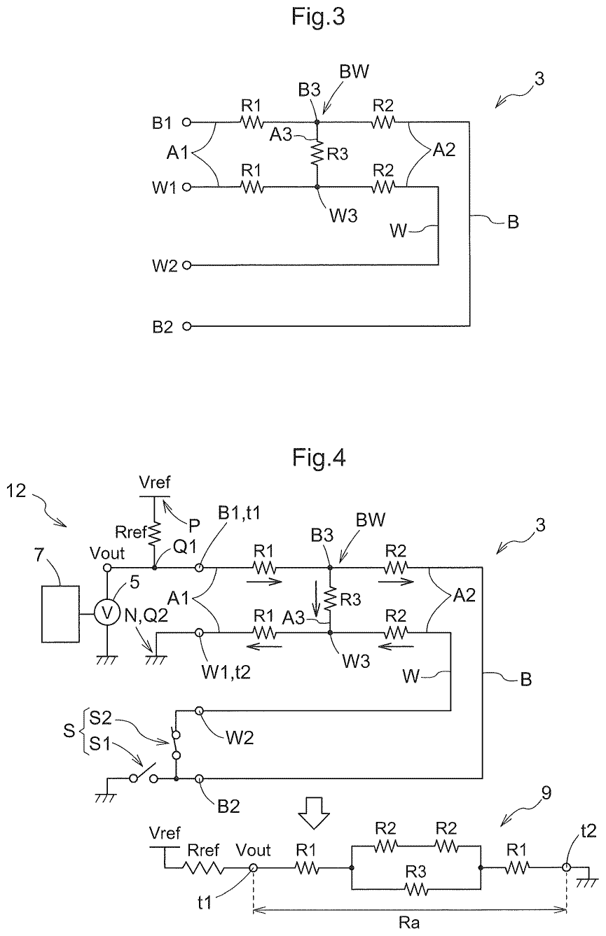

FIG. 3 shows an equivalent circuit of a thermal line 3 having a short circuit. When the first conductive wire B and the second conductive wire W are short-circuited at the short-circuited site BW, the contact of the first conductive wire B at the short-circuited site BW is referred to as a first short-circuit point B3, and the contact of the second conductive wire W at the short-circuited site BW is referred to as a second short-circuit point W3. The first short-circuit point B3, the second short-circuit point W3, the first contact B1, the second contact B2, the third contact W1, and the fourth contact W2 are contacts (nodes) in this equivalent circuit. A branch (or an arm) from the first contact B1 to the first short-circuit point B3, and a branch from the third contact W1 to the second short-circuit point W3 are referred to as first branches A1. As shown in the equivalent circuit in FIG. 3, the branch from the first contact B1 to the first short-circuit point B3 and the branch from the third contact W1 to the second short-circuit point W3 have first resistances R1, which can be substantially the same, and are both referred to as the first branches A1. A branch from the first short-circuit point B3 to the second contact B2 and a branch from the second short-circuit point W3 to the fourth contact W2 are referred to as second branches A2. As shown in the equivalent circuit in FIG. 3, the branch from the first short-circuit point B3 to the second contact B2 and the branch from the second short-circuit point W3 to the fourth contact W2 have second resistances R2, which can be substantially the same, and are both referred to as the second branches A2. A branch between the first short-circuit point B3 and the second short-circuit point W3 and having a third resistance R3 is referred to as a third branch A3.

For example, a resistance (R1+R3+R1) between the first end (first contact B1) of the first conductive wire B and the first end (third contact W1) of the second conductive wire W and a resistance (R1+R3+R2) between the first end (first contact B1) of the first conductive wire B and a second end (fourth contact W2) of the second conductive wire W are measured. When the third resistance R3, or a resistance at the short-circuited site BW, is estimated to be zero, the resistance between the first contact B1 and the third contact W1 is R1+R1, and the resistance between the first contact B1 and the fourth contact W2 is R1+R2. Thus, the first resistance R1 can be calculated from the resistance between the first contact B1 and the third contact W1, and the second resistance R2 can be calculated from the first resistance R1 and the resistance between the first contact B1 and the fourth contact W2.

The entire resistance of the first conductive wire B (resistance between the first contact B1 and the second contact B2) and the entire resistance of the second conductive wire W (resistance between the third contact W1 and the fourth contact W2) can be substantially equal to each other, and thus are both known to be R1+R2. The length and the resistance of the conductive wire 1 have a linear relationship. Thus, the ratio between the first resistance R1 and the second resistance R2 can be used to estimate the first short-circuit point B3 and the second short-circuit point W3 and to identify the short-circuit site BW.

However, when the first conductive wire B and the second conductive wire W are short-circuited, the first conductive wire B and the second conductive wire W at the short-circuited site BW may be in contact with each other in various manners, and thus the resistance may vary. When, for example, the insulators 2 between the first conductive wire B and the second conductive wire W soften gradually, the first conductive wire B and the second conductive wire W may be short-circuited while having a relatively large resistance. In this case as well, heat generation of the feed line 8 is to be detected promptly to accurately identify the short-circuited site BW generating heat. However, when the third resistance R3, or the resistance between the first conductive wire B and the second conductive wire W at the short-circuited site, is estimated to be zero as in the above manner, estimation of the short-circuited site can have a larger error. The heat detection device 10 according to the present embodiment includes the short-circuit position detector 12 that can accurately identify the short-circuited site BW based on the third resistance R3, or the resistance between the first conductive wire B and the second conductive wire W at the short-circuited site BW.

For example, the article transport facility 100 illustrated in the embodiment includes the first conductive wire B and the second conductive wire W with a long full length. As described above with reference to FIG. 1, when the article transport vehicle 50 is a ceiling-hung transport vehicle, the feed lines 8 and the thermal lines 3 are disposed higher from the floor. More specifically, the first conductive wire B and the second conductive wire W are often installed at positions that are not viewable easily. In particular, the article transport facility 100 illustrated in the present embodiment including the short-circuit position detector 12 is highly effective to identify the site at which any thermal line 3 is short-circuited, or to identify the site at which any feed line 8 has a high temperature.

Thus, the present embodiment describes the heat detection device 10 in the article transport facility 100 that detects the feed line 8 as a detection target. However, the detection target for heat generation is not limited to the feed line 8. A facility or a device including the heat detection device 10 is also not limited to the article transport facility 100.

The structure will be described with reference to FIGS. 4 to 6. As shown in FIG. 4 and other figures, the equivalent circuit in FIG. 3 includes a first target contact t1, a second target contact t2, a first reference contact Q1, and a second reference contact Q2. The short-circuit position detector 12 includes a voltage detector 5 and a switch S, in addition to the first target contact t1, the second target contact t2, the first reference contact Q1, and the second reference contact Q2.

The first target contact t1 is selected from at least one of the first contact B1, the second contact B2, the third contact W1, or the fourth contact W2. The second target contact t2 is selected from at least one of the first contact B1, the second contact B2, the third contact W1, or the fourth contact W2 excluding the first target contact t1.

A reference resistance Rref is connected to at least one of a positive electrode P (reference voltage Vref) or a negative electrode N (ground) of the short-circuit position detector 12. FIG. 4 and other figures show the reference resistance Rref connected to the positive electrode P, but the reference resistance Rref may be connected to the negative electrode N or connected to each of the positive electrode P and the negative electrode N. The reference resistance Rref connected to the positive electrode P and the reference resistance Rref connected to the negative electrode N may have the same resistance or different resistances. The reference voltage Vref is divided into the reference resistance Rref and a combined resistance (a first combined resistance Ra, a second combined resistance Rb, and a third combined resistance Rc) described later. A voltage between the two ends of the combined resistance is a target voltage Vout of the detection target. The positive electrode P may be the same as the positive electrode (Vp) of the short-circuit detection device 11. The negative electrode N may be the same as the negative electrode (ground) of the short-circuit detection device 11.

The first reference contact Q1 is nearer the positive electrode P and is connected to the positive electrode P or connected to the positive electrode P through the reference resistance Rref. The second reference contact Q2 is nearer the negative electrode N and is connected to the negative electrode N or connected to the negative electrode N through the reference resistance Rref. The target voltage Vout is detected to identify the short-circuited site BW. The target voltage Vout is a voltage between the first target contact t1 and the second target contact t2. In the present embodiment, as shown in FIG. 4 and other figures, the second target contact t2 is connected to the negative electrode N. The target voltage Vout is thus a voltage between the first target contact t1 and the ground. The voltage detector 5 detects the target voltage Vout. Although the voltage detector 5 may be a voltage sensor as shown conceptually in FIGS. 4 to 6, the voltage sensor may be eliminated. For example, when the controller 7 includes a microcomputer including a functional component that determines the voltage of an analog signal such as an analog-to-digital (A/D) converter, the microcomputer may serve as the voltage detector 5. In particular, when the target voltage Vout is a voltage between the first target contact t1 and the ground as in the present embodiment, such a microcomputer can easily detect the voltage.

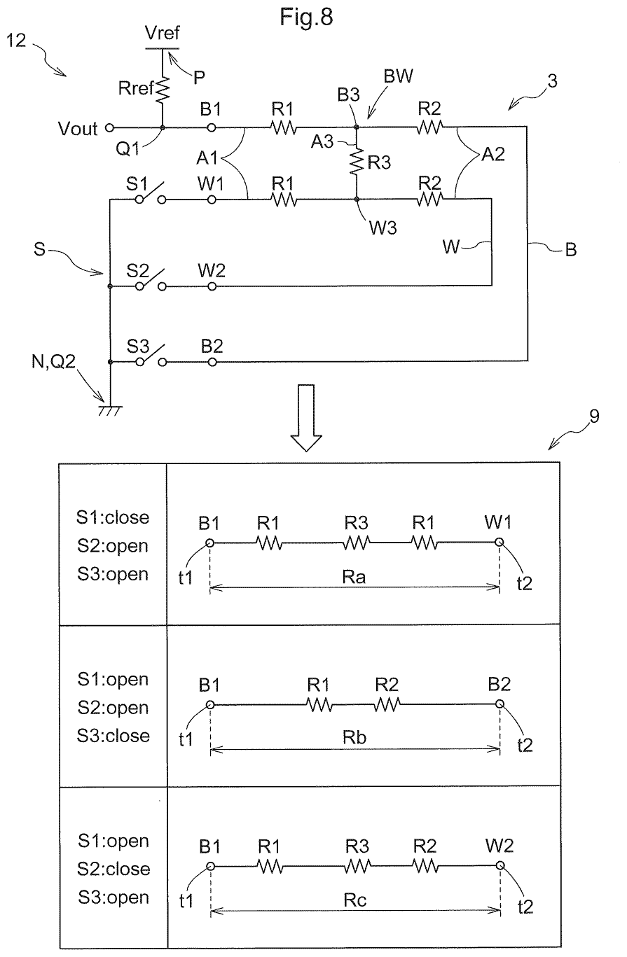

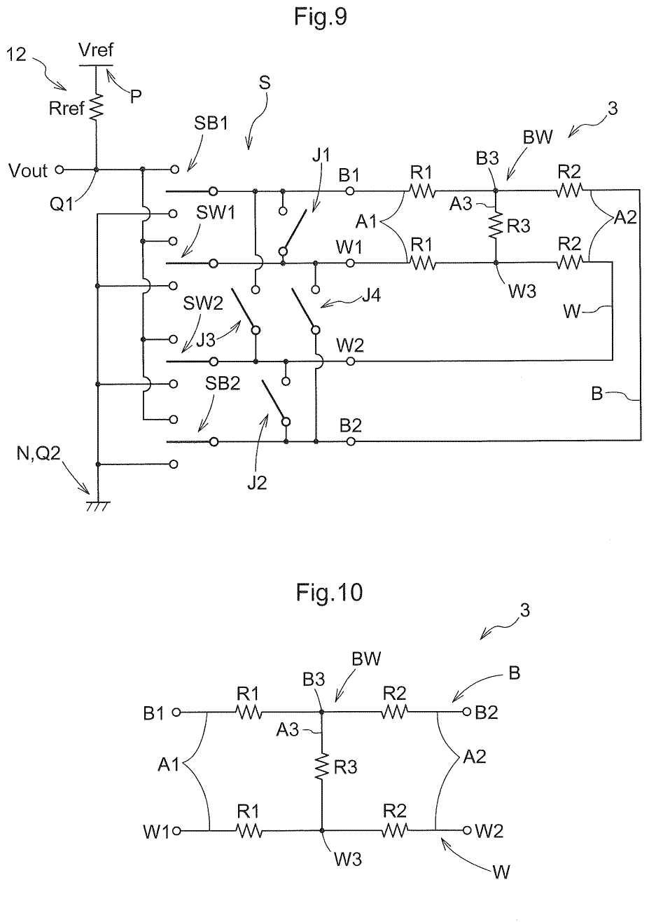

The switch S includes at least one make-break contact (the first contactor S1 and the second contactor S2 shown in FIGS. 4 to 6). Although described in detail later, as shown in FIG. 8, the switch S may further include a third contactor S3. Although described in detail later as well, as shown in FIG. 9, the switch S may further include a first contact contactor SB1, a second contact contactor SB2, a third contact contactor SW1, and a fourth contact contactor SW2. The short-circuit position detector 12 in the present embodiment includes the switch S including at least two make-break contacts. More specifically, the switch S switches electric connection between at least the first contact B1, the second contact B2, the third contact W1, or the fourth contact W2 and the first reference contact Q1 or the second reference contact Q2 to switch the circuit configuration of the two-terminal circuit 9 including the first target contact t1 and the second target contact t2 as terminals. Various embodiments will be described below. The switch S switches the connection of the first branches A1, the second branches A2, and the third branch A3 to cause the first branches A1, the second branches A2, and the third branch A3 to be included in at least one two-terminal circuit 9 and to form at least three different two-terminal circuits 9.

In the examples shown in FIGS. 4 to 6, the switch S includes the first contactor S1 and the second contactor S2. The structure of the switch S including two contactors is the structure of the switch S including the fewest contactors. The first contactor S1 can connect or disconnect the second contact B2 to or from the negative electrode N (ground). The second contactor S2 can connect or disconnect the second contact B2 to or from the fourth contact W2. The first contactor S1 and the second contactor S2 can connect the second contact B2 and the fourth contact W2 to the negative electrode N (ground) in cooperation. FIGS. 4 to 6 show examples of different two-terminal circuits 9 in which the first contactor S1 and the second contactor S2 are open or closed in different manners.

In FIGS. 4 to 6, the arrows denote the current directions. In the examples in FIGS. 4 to 6, the first target contact t1 is fixed to the first contact B1, and the first contact B1 is connected to the first reference contact Q1. Thus, the first contact B1 has a voltage of the target voltage Vout. The second target contact t2 includes at least the third contact W1. In other words, the third contact W1 is fixed to the second target contact t2. When the first contactor S1 is closed, the second contact B2 also serves as the second target contact t2. When the first contactor S1 and the second contactor S2 are closed, the second contact B2 and the fourth contact W2 also serve as the second target contacts t2.

As described above, the second contactor S2 can connect or disconnect the second contact B2 to or from the fourth contact W2. More specifically, in addition to a make-break contact that switches electric connection between the first contact B1, the second contact B2, the third contact W1, or the fourth contact W2 and the first reference contact Q1 or the second reference contact Q2, the switch S may further include a make-break contact that can connect two of the first contact B1, the second contact B2, the third contact W1, and the fourth contact W2 in different conductive wires 1 to each other. As described later with reference to FIG. 9, a first jumper J1, a second jumper J2, a third jumper J3, and a fourth jumper J4 may be included as make-break contacts that can connect two contacts of different conductive wires 1 to each other. The second contactor S2 in FIGS. 4 to 6 is a make-break contact corresponding to the second jumper J2 in the example in FIG. 9.

In the example in FIG. 4, the first contactor S1 is open, and the second contactor S2 is closed. The combined resistance (first combined resistance Ra) of the two-terminal circuit 9 (the same as No. 8 in FIG. 11) is calculated with Formula 1 below.

$$Ra = R 1 + \frac{1}{\frac{1}{R 2 + R 2} + \frac{1}{R 3}} + R 1 = 2 \cdot R 1 + \frac{2 \cdot R 2 \cdot R 3}{2 \cdot R 2 + R 3} \qquad ( 1 )$$

As shown in FIG. 4, the target voltage Vout of the detection target is the voltage between the positive electrode P and the negative electrode N that is divided into the reference resistance Rref and the first combined resistance Ra. The current that may flow through the reference resistance Rref and the current flowing through the first combined resistance Ra are the same, and Formula 2 is thus derived.

$$\frac{V ref - V out}{Rref} = \frac{V out}{Ra} \qquad ( 2 )$$

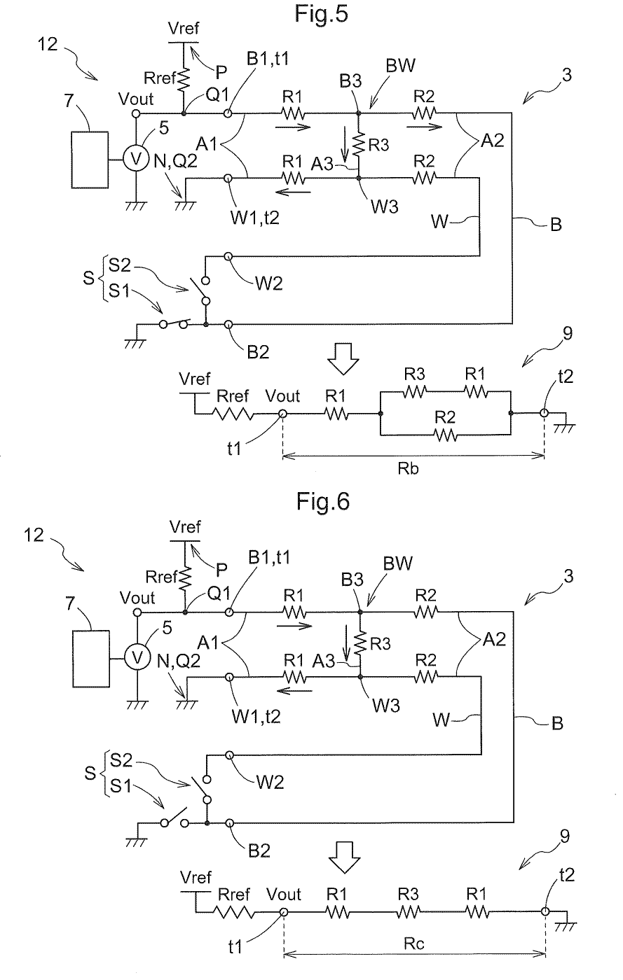

The target voltage Vout is detected by the voltage detector 5, and the reference resistance Rref is known. Thus, the first combined resistance Ra can be calculated from Formula 3 below. A second combined resistance Rb or a third combined resistance Rc described later with reference to FIGS. 5 and 6 is calculated in the same manner by reading Ra in Formula 3 as Rb or Rc.

$$Ra = \frac{V out}{V ref - V out} \cdot Rref \qquad ( 3 )$$

Similarly, in the example in FIG. 5, the first contactor S1 is closed, and the second contactor S2 is open. The combined resistance (second combined resistance Rb) of the two-terminal circuit 9 (the same as No. 5 in FIG. 11) is calculated with Formula 4 below.

$$Rb = R 1 + \frac{1}{\frac{1}{R 3 + R 1} + \frac{1}{R 2}} = R 1 + \frac{R 2 \cdot ( R 1 + R 3 )}{R 1 + R 2 + R 3} \qquad ( 4 )$$

Similarly, in the example in FIG. 6, the first contactor S1 and the second contactor S2 are both open. The combined resistance (third combined resistance Rc) of the two-terminal circuit 9 (the same as No. 3 in FIG. 11) is calculated with Formula 5 below.

$$Rc = R 1 + R 3 + R 1 = 2 \cdot R 1 + R 3 \qquad ( 5 )$$

The short-circuit position detector 12 can calculate the first resistance R1, the second resistance R2, and the third resistance R3 by solving simultaneous equations in Formulas 1, 4, and 5 using the first combined resistance Ra, the second combined resistance Rb, and the third combined resistance Rc calculated from Formula 3.

More specifically, the short-circuit position detector 12 calculates the combined resistances (the first combined resistance Ra, the second combined resistance Rb, and the third combined resistance Rc) of at least three different two-terminal circuits 9 based on the reference voltage Vref that is the voltage between the positive electrode P and the negative electrode N, the resistance of the reference resistance Rref, and the target voltage Vout (Formula 3). The short-circuit position detector 12 then calculates the first resistance R1, the second resistance R2, and the third resistance R3 based on the multiple combined resistances (the first combined resistance Ra, the second combined resistance Rb, and the third combined resistance Rc). The first resistance R1 is the resistance of the first branches A1. The second resistance R2 is the resistance of the second branches A2. The first conductive wire B and the second conductive wire W each include the first branch A1 and the second branch A2. Thus, the short-circuited site BW can be estimated based on at least one of the first resistance R1 or the second resistance R2.

In an example, the short-circuit position detector 12 can estimate the short-circuited site BW based on the resistances of the first conductive wire B and the second conductive wire W per unit length and the first resistance R1 or the second resistance R2. The short-circuit position detector 12 may estimate the short-circuited site BW based on the full length of the first conductive wire B and the second conductive wire W and the ratio between the first resistance R1 and the second resistance R2. The length of the conductive wire 1 and the resistance of the conductive wire 1 have a linear relationship, and thus the short-circuited site BW can be estimated accurately.

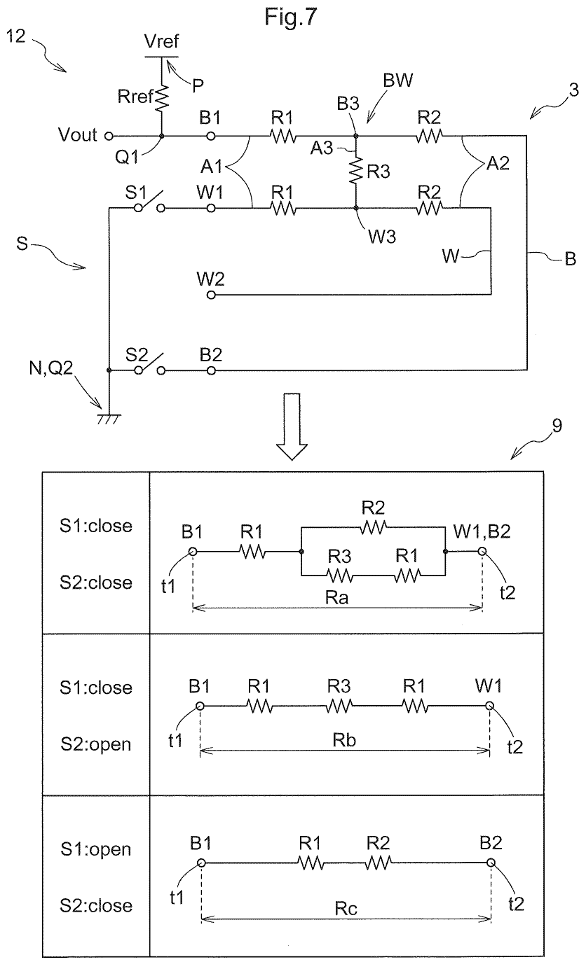

As described above, the short-circuit position detector 12 calculates the combined resistances (the first combined resistance Ra, the second combined resistance Rb, and the third combined resistance Rc) of at least three different two-terminal circuits 9, and calculates the first resistance R1, the second resistance R2, and the third resistance R3 based on the combined resistances (the first combined resistance Ra, the second combined resistance Rb, and the third combined resistance Rc). The switch S may include a make-break contact to form at least three different two-terminal circuits 9. Although FIGS. 4 to 6 show examples further including a jumper (second contactor S2) serving as a make-break contact, each structure may simply include a make-break contact that switches electric connection between the first contact B1, the second contact B2, the third contact W1, or the fourth contact W2 and the first reference contact Q1 or the second reference contact Q2 without the jumper. FIGS. 7 and 8 show examples in which the switch S not including a jumper as a make-break contact switches electric connection.

FIG. 7 shows an example circuit configuration that can form three different two-terminal circuits 9 with the fewest make-break contacts without a jumper. In this example, the first contactor S1 selectively connects or disconnects the third contact W1 to or from the second reference contact Q2 (ground), and the second contactor S2 selectively connects or disconnects the second contact B2 to or from the second reference contact Q2 (ground). When the first contactor S1 and the second contactor S2 are both closed, the two-terminal circuit 9 as in No. 5 in FIG. 11 and in FIG. 5 is formed. When the first contactor S1 is closed and the second contactor S2 is open, the two-terminal circuit 9 as in No. 3 in FIG. 11 and in FIG. 6 is formed. When the first contactor S1 is open and the second contactor S2 is closed, the two-terminal circuit 9 as in No. 1 in FIG. 11 is formed.

FIG. 8 shows an example circuit configuration that can form three different two-terminal circuits 9 with the simplest combined resistance without a jumper. In this example, the switch S includes three make-break contacts, the first contactor S1 selectively connects or disconnects the third contact W1 to or from the second reference contact Q2 (ground), the second contactor S2 selectively connects or disconnects the fourth contact W2 to or from the second reference contact Q2 (ground), and the third contactor S3 selectively connects or disconnects the second contact B2 to or from the second reference contact Q2 (ground).

When the first contactor S1 is closed, the second contactor S2 is open, and the third contactor S3 is open, the two-terminal circuit 9 as in No. 3 in FIG. 11 and in FIG. 6 is formed. When the first contactor S1 is open, the second contactor S2 is open, and the third contactor S3 is closed, the two-terminal circuit 9 as in No. 1 in FIG. 11 is formed. When the first contactor S1 is open, the second contactor S2 is closed, and the third contactor S3 is open, the two-terminal circuit 9 as in No. 2 in FIG. 11 is formed.

As described above with reference to FIGS. 4 to 8, the short-circuit position detector 12 can identify the short-circuited site BW as appropriate when the switch S switches the connection of the first branches A1, the second branches A2, and the third branch A3 to cause the first branches A1 each including the first resistance R1, the second branches A2 each including the second resistance R2, and the third branch A3 including the third resistance R3 to be included in at least one two-terminal circuit 9 and to form at least three different two-terminal circuits 9. The short-circuit position detector 12 may have any structure that can form at least three two-terminal circuits 9 formed from the short-circuited equivalent circuit shown in FIG. 3. As shown in FIGS. 11 to 13, the inventors can form 58 types of such two-terminal circuits 9.

FIG. 9 shows an example of the switch S including make-break contacts that can form any of 58 types of the two-terminal circuits 9. The switch S in FIG. 9 includes eight make-break contacts, or more specifically, the first contact contactor SB1, the second contact contactor SB2, the third contact contactor SW1, the fourth contact contactor SW2, the first jumper J1, the second jumper J2, the third jumper J3, and the fourth jumper J4.

When the first contact contactor SB1 connected to two different contacts is closed, the first contact contactor SB1 exclusively connects the first contact B1 to the first reference contact Q1 and to the second reference contact Q2. When the first contact contactor SB1 is open, the first contact contactor SB1 opens the first contact B1. Similarly, when the second contact contactor SB2 is closed, the second contact contactor SB2 exclusively connects the second contact B2 to the first reference contact Q1 and to the second reference contact Q2. When the second contact contactor SB2 is open, the second contact contactor SB2 opens the second contact B2. Similarly, when the third contact contactor SW1 is closed, the third contact contactor SW1 exclusively connects the third contact W1 to the first reference contact Q1 and to the second reference contact Q2. When the third contact contactor SW1 is open, the third contact contactor SW1 opens the third contact W1. Similarly, when the fourth contact contactor SW2 is closed, the fourth contact contactor SW2 exclusively connects the fourth contact W2 to the first reference contact Q1 and to the second reference contact Q2. When the fourth contact contactor SW2 is open, the fourth contact contactor SW2 opens the second contact B2.

The first contact contactor SB1, the second contact contactor SB2, the third contact contactor SW1, and the fourth contact contactor SW2 each include a make-break contact that is connectable, although exclusively, to the first reference contact Q1 and to the second reference contact Q2. The short-circuit position detector 12 shown in FIG. 9 can thus include eight switches (four switches each including one make-break contact and four switches each including two make-break contacts) and include twelve make-break contacts.

The first jumper J1, the second jumper J2, the third jumper J3, and the fourth jumper J4 are switches each including a single make-break contact. The first jumper J1 connects or disconnects the first contact B1 to or from the third contact W1. The second jumper J2 connects or disconnects the second contact B2 to or from the fourth contact W2. The third jumper J3 connects or disconnects the first contact B1 to or from the fourth contact W2. The fourth jumper J4 connects or disconnects the second contact B2 to or from the third contact W1.

As clearly described above with reference to FIGS. 4 to 8, to form the fewest three two-terminal circuits 9, the switch S may not include all the make-break contacts shown in FIG. 9. Thus, the switch S included in the short-circuit position detector 12 may not include all the make-break contacts shown in FIG. 9.

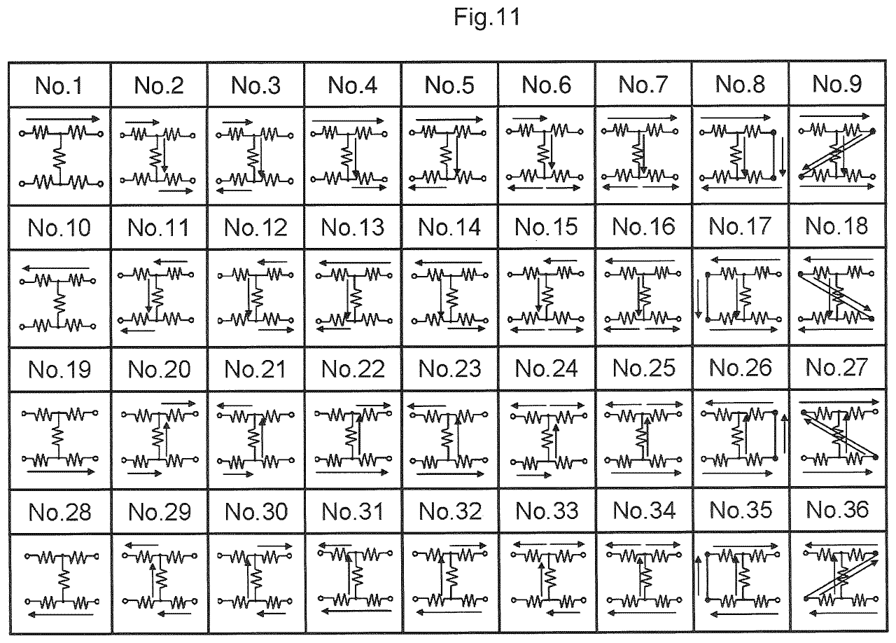

FIG. 10 shows a two-terminal pair circuit (four-terminal circuit) from which the two-terminal circuits 9 are formed by switching the connection of the first branches A1, the second branches A2, and the third branch A3. FIGS. 11 to 13 show 58 different states of connection to form the two-terminal circuits from the two-terminal pair circuit. The arrows in FIGS. 11 to 13 indicate the current directions. The trailing end of each arrow at the first contact B1, the second contact B2, the third contact W1, or the fourth contact W2 indicates that the contact is connected to the first reference contact Q1. More specifically, the trailing end of the arrow corresponds to the first target contact t1 having the target voltage Vout. The leading end of each arrow at the first contact B1, the second contact B2, the third contact W1, or the fourth contact W2 indicates that the contact is connected to the second reference contact Q2 (ground). Two of the first contact B1, the second contact B2, the third contact W1, and the fourth contact W2 are solid and connected with a line. This indicates that these two contacts are connected to each other with any of the first jumper J1, the second jumper J2, the third jumper J3, or the fourth jumper J4.

FIG. 11 shows circuit examples in which one of the first contact B1, the second contact B2, the third contact W1, and the fourth contact W2 simply serves as the first target contact t1. For circuit examples Nos. 1 to 9 are circuit examples in which the first contact B1 serves as the first target contact t1. For circuit examples Nos. 10 to 18 are circuit examples in which the second contact B2 serves as the first target contact t1. For circuit examples Nos. 19 to 27 are circuit examples in which the third contact W1 serves as the first target contact t1. For circuit examples Nos. 28 to 36 are circuit examples in which the fourth contact W2 serves as the first target contact t1.

FIG. 12 shows circuit examples in which two of the first contact B1, the second contact B2, the third contact W1, and the fourth contact W2 serve as the first target contacts t1. For circuit examples Nos. 37 to 39, the first contact B1 and the second contact B2 serve as the first target contacts t1. For circuit examples Nos. 40 to 42, the first contact B1 and the fourth contact W2 serve as the first target contacts t1. For circuit examples Nos. 43 to 45, the first contact B1 and the third contact W1 serve as the first target contacts t1. For circuit examples Nos. 46 to 48, the second contact B2 and the fourth contact W2 serve as the first target contacts t1. For circuit examples Nos. 49 to 51, the second contact B2 and the third contact W1 serve as the first target contacts t1. For circuit examples Nos. 52 to 54, the third contact W1 and the fourth contact W2 serve as the first target contacts t1.

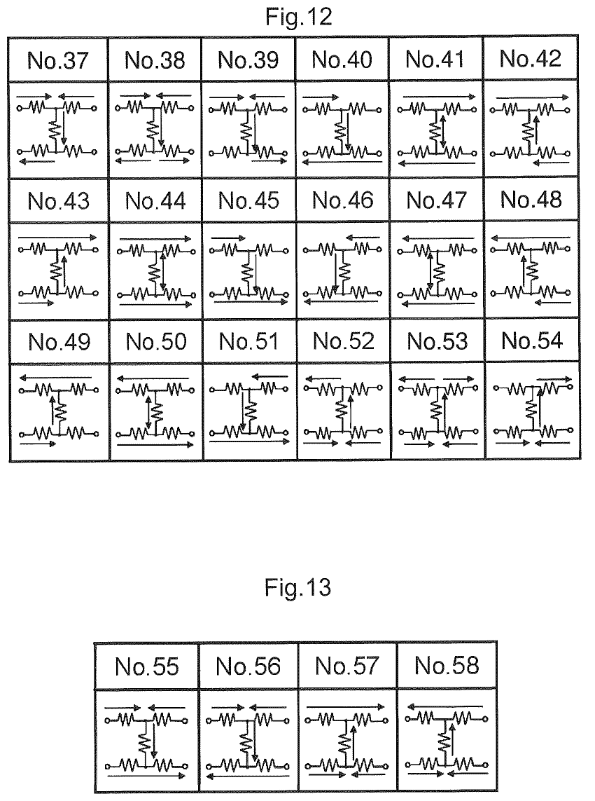

FIG. 13 shows circuit examples in which three of the first contact B1, the second contact B2, the third contact W1, and the fourth contact W2 serve as the first target contacts t1. For circuit example No. 55, the first contact B1, the second contact B2, and the third contact W1 serve as the first target contacts t1. For circuit example No. 56, the first contact B1, the second contact B2, and the fourth contact W2 serve as the first target contacts t1. For circuit example No. 57, the first contact B1, the third contact W1, and the fourth contact W2 serve as the first target contacts t1. For circuit example No. 58, the second contact B2, the third contact W1, and the fourth contact W2 serve as the first target contacts t1.

The heat detection device described above is outlined below.

A heat detection device according to one aspect includes a first conductive wire, a second conductive wire, and a short-circuit position detector. The first conductive wire includes a first contact and a second contact at opposite ends of the first conductive wire. The second conductive wire includes a third contact and a fourth contact at opposite ends of the second conductive wire. The second conductive wire is adjacent to the first conductive wire along a detection target with an insulator between the first conductive wire and the second conductive wire. The insulator softens at a preset temperature. The short-circuit position detector detects a short-circuited site at which the first conductive wire and the second conductive wire are short-circuited. The heat detection device detects heat generation of the detection target by detecting a short circuit between the first conductive wire and the second conductive wire. The short circuit results from the insulator softening with heat. The short-circuit position detector includes a first target contact selected from at least one of the first contact, the second contact, the third contact, or the fourth contact, a second target contact selected from at least one of the first contact, the second contact, the third contact, or the fourth contact excluding the first target contact, a reference resistance connected to at least one of a positive electrode or a negative electrode, a first reference contact connected to the positive electrode or connected to the positive electrode through the reference resistance, a second reference contact connected to the negative electrode or connected to the negative electrode through the reference resistance, a voltage detector that detects a target voltage between the first target contact and the second target contact, and a switch including at least one make-break contact. The switch switches electric connection between at least the first contact, the second contact, the third contact, or the fourth contact and the first reference contact or the second reference contact to switch a circuit configuration of two-terminal circuits each including the first target contact and the second target contact as terminals. The switch switches, in response to the first conductive wire and the second conductive wire being short-circuited at the short-circuited site, connection of first branches, second branches, and a third branch to cause the first branches, the second branches, and the third branch to be included in at least one of the two-terminal circuits and to form at least three two-terminal circuits each including the first target contact and the second target contact as terminals. The first branches are branches having substantially a same first resistance and are a branch extending from the first contact to a first short-circuit point and a branch extending from the third contact to a second short-circuit point. The second branches are branches having substantially a same second resistance and are a branch extending from the first short-circuit point to the second contact and a branch extending from the second short-circuit point to the fourth contact. The third branch is a branch having a third resistance and extending between the first short-circuit point and the second short-circuit point. The first short-circuit point is a contact at the short-circuited site in the first conductive wire. The second short-circuit point is a contact at the short-circuited site in the second conductive wire.

The heat detection device with this structure includes the switch that switches the connection between the first conductive wire or the second conductive wire and the first reference contact nearer the positive electrode or the second reference contact nearer the negative electrode to form the at least three two-terminal circuits. Each two-terminal circuit includes at least one of an unknown first resistance, an unknown second resistance, or an unknown third resistance. With simultaneous equations based on the three two-terminal circuits, the unknown three resistances can be determined. Determining the third resistance that may vary depending on the form of a short circuit at the short-circuited site allows accurate determination of the first resistance and the second resistance. The resistance of the conductive wire has a linear relationship with the length of the conductive wire. Thus, determining the resistance of the conductive wire, or the first resistance and the second resistance, allows accurate estimation of the short-circuited site. More specifically, the heat detection device with this structure can accurately identify the short-circuited site based on the resistance between the first conductive wire and the second conductive wire at the short-circuited site.

The at least one make-break contact in the switch may include a make-break contact that connects two contacts of the first contact, the second contact, the third contact, or the fourth contact. The two contacts may be in different conductive wires.

The heat detection device with this structure can form more types of two-terminal circuits than when switching electric connection between the first contact, the second contact, the third contact, or the fourth contact and the first reference contact or the second reference contact.

The short-circuit position detector may calculate a combined resistance of each of the at least three two-terminal circuits based on a voltage between the positive electrode and the negative electrode, a resistance of the reference resistance, and the target voltage, calculate the first resistance, the second resistance, and the third resistance based on the combined resistance of each of the at least three two-terminal circuits, and estimate the short-circuited site based on at least one of the first resistance or the second resistance.

Each two-terminal circuit includes at least one of an unknown first resistance, an unknown second resistance, or an unknown third resistance. With simultaneous equations based on the combined resistance of the three different resistances, the unknown three resistances can be determined. Determining the third resistance that may vary depending on the form of a short circuit at the short-circuited site allows accurate determination of the first resistance and the second resistance. The first resistance has a linear relationship with the length of each first branch, and the second resistance has a linear relationship with the length of each second branch, similarly to the entire resistance of the first conductive wire and the second conductive wire having a linear relationship with the full length of the first conductive wire and the second conductive wire. Thus, determining the first resistance and the second resistance allows accurate determination of the lengths of the first and second branches. The short-circuited site can thus be identified accurately.

The short-circuit position detector may estimate the short-circuited site based on a full length of each of the first conductive wire and the second conductive wire and a ratio between the first resistance and the second resistance.

The length of the conductive wire and the resistance of the conductive wire have a linear relationship. Thus, the ratio between the first resistance and the second resistance is equivalent to the ratio between the length of the first branch and the length of the second branch in the first conductive wire, and equivalent to the ratio between the length of the first branch and the length of the second branch in the second conductive wire. The heat detection device with this structure can thus accurately estimate the short-circuited site.

The short-circuit position detector may estimate the short-circuited site based on resistances of the first conductive wire and the second conductive wire per unit length and based on the first resistance or the second resistance.

The length of the conductive wire and the resistance of the conductive wire have a linear relationship. Thus, the first resistance and the resistance per unit length have a linear relationship with the length of each first branch, and the second resistance and the resistance per unit length have a linear relationship with the length of each second branch. The heat detection device with this structure can thus accurately estimate the short-circuited site.

What is claimed is:

1. A heat detection device, comprising:
a first conductive wire comprising a first contact and a second contact at opposite ends of the first conductive wire;
a second conductive wire comprising a third contact and a fourth contact at opposite ends of the second conductive wire, the second conductive wire adjacent to the first conductive wire along a detection target with an insulator between the first conductive wire and the second conductive wire, and the insulator configured to soften at a preset temperature; and
a short-circuit position detector configured to detect a short-circuited site at which the first conductive wire and the second conductive wire are short-circuited, and
wherein:
the heat detection device is configured to detect heat generation of the detection target by detecting a short circuit between the first conductive wire and the second conductive wire, the short circuit resulting from the insulator softening with heat,
the short-circuit position detector comprises:
a first target contact selected from at least one of the first contact, the second contact, the third contact, or the fourth contact,
a second target contact selected from at least one of the first contact, the second contact, the third contact, or the fourth contact excluding the first target contact,
a reference resistance connected to at least one of a positive electrode or a negative electrode,
a first reference contact connected to the positive electrode or connected to the positive electrode through the reference resistance,
a second reference contact connected to the negative electrode or connected to the negative electrode through the reference resistance,
a voltage detector configured to detect a target voltage between the first target contact and the second target contact, and
a switch comprising at least one make-break contact,
the switch is configured to switch electric connection between at least the first contact, the second contact, the third contact, or the fourth contact and the first reference contact or the second reference contact to switch a circuit configuration of two-terminal circuits each including the first target contact and the second target contact as terminals,
the switch is configured to switch, in response to the first conductive wire and the second conductive wire being short-circuited at the short-circuited site, connection of first branches, second branches, and a third branch to cause the first branches, the second branches, and the third branch to be included in at least one of the two-terminal circuits and to form at least three two-terminal circuits each including the first target contact and the second target contact as terminals,
the first branches are branches having substantially a same first resistance, and the first branches are a branch extending from the first contact to a first short-circuit point and a branch extending from the third contact to a second short-circuit point,
the second branches are branches having substantially a same second resistance, and the second branches are a branch extending from the first short-circuit point to the second contact and a branch extending from the second short-circuit point to the fourth contact,
the third branch is a branch having a third resistance and extending between the first short-circuit point and the second short-circuit point,
the first short-circuit point is a contact at the short-circuited site in the first conductive wire,
the second short-circuit point is a contact at the short-circuited site in the second conductive wire.

2. The heat detection device according to claim 1, wherein:
the at least one make-break contact in the switch comprises a make-break contact configured to connect two contacts of the first contact, the second contact, the third contact, or the fourth contact, and the two contacts are in different conductive wires.

3. The heat detection device according to claim 1, wherein the short-circuit position detector:
calculates a combined resistance of each of the at least three two-terminal circuits based on a voltage between the positive electrode and the negative electrode, a resistance of the reference resistance, and the target voltage,
calculates the first resistance, the second resistance, and the third resistance based on the combined resistance of each of the at least three two-terminal circuits, and
estimates the short-circuited site based on at least one of the first resistance or the second resistance.

4. The heat detection device according to claim 3, wherein:
the short-circuit position detector estimates the short-circuited site based on a full length of each of the first conductive wire and the second conductive wire and a ratio between the first resistance and the second resistance.

5. The heat detection device according to claim 3, wherein:
the short-circuit position detector estimates the short-circuited site based on resistances of the first conductive wire and the second conductive wire per unit length and based on the first resistance or the second resistance.
